(19) United States
(12) Patent Application Publication
(10) Pub. No.: US 2024/0153996 A1
(43) Pub. Date: May 9, 2024

(54) SEMICONDUCTOR DEVICE

(71) Applicant: ROHM CO., LTD., Kyoto (JP)

(72) Inventor: Junya IKEDA, Kyoto (JP)

(73) Assignee: ROHM CO., LTD., Kyoto (JP)

(21) Appl. No.: 18/502,112

(22) Filed: Nov. 6, 2023

(30) Foreign Application Priority Data
Nov. 8, 2022 (JP) 2022-178928

(51) Int. Cl. H01L 29/06; H01L 29/08; H01L 29/735; H01L 29/78

(52) U.S. Cl. CPC H01L 29/0696; H01L 29/0821; H01L 29/735; H01L 29/7816

(57) ABSTRACT

A semiconductor device includes: a semiconductor layer having a surface; a first region and a second region of a first conductivity type, which are spaced apart from each other in a first direction on the surface and extend in a second direction orthogonal to the first direction, when viewed from a thickness direction orthogonal to the surface; a channel region of a second conductivity type; a gate electrode arranged on the channel region via a gate insulating film; a plurality of drift regions of a first conductivity type and a plurality of column regions of the second conductivity type; a buffer region of the first conductivity type; and at least one collector region of the second conductivity type.

### CROSS-REFERENCE TO RELATED APPLICATION

This application is based upon and claims the benefit of priority from Japanese Patent Application No. 2022-178928 filed on Nov. 8, 2022, the entire contents of which are incorporated herein by reference.

### TECHNICAL FIELD

The present disclosure relates to a semiconductor device.

### BACKGROUND

The related art discloses a semiconductor device including a MOSFET (Metal Oxide Semiconductor Field Effect Transistor) having a super junction structure.

### BRIEF DESCRIPTION OF DRAWINGS

The accompanying drawings, which are incorporated in and constitute a part of the specification, illustrate embodiments of the present disclosure.

FIG. 1 is a schematic plan view of an exemplary semiconductor device according to an embodiment.

FIG. 2 is a cross-sectional view of the semiconductor device, which is taken along line F2-F2 in FIG. 1.

FIG. 3 is a cross-sectional view of the semiconductor device, which is taken along line F3-F3 in FIG. 1.

FIG. 4 is a perspective view of the semiconductor device of FIG. 1.

FIG. 5 is a schematic plan view of an exemplary semiconductor device according to a modification.

FIG. 6 is a schematic plan view of an exemplary semiconductor device according to a modification.

FIG. 7 is a schematic cross-sectional view of an exemplary semiconductor device according to a modification.

FIG. 8 is a schematic cross-sectional view of an exemplary semiconductor device according to a modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, some embodiments of a semiconductor device of the present disclosure will be described with reference to the accompanying drawings. It should be noted that, for simplicity and clarity of explanation, components shown in the drawings are not necessarily drawn to scale. Further, in order to facilitate understanding, hatching lines may be omitted in cross-sectional views. The accompanying drawings merely illustrate embodiments of the present disclosure and should not be considered as limiting the present disclosure. The terms such as “first,” “second,” and “third” in the present disclosure are used merely to distinguish between objects and are not intended to rank the objects.

The following detailed description includes devices, systems, and methods embodying exemplary embodiments of the present disclosure. This detailed description is for descriptive purposes only and is not intended to limit the embodiments of the present disclosure or the applications and uses of such embodiments.

The expression “at least one” as used herein means “one or more” of desired options. As an example, if there are two options, the expression “at least one” as used herein means “only one option” or “both of the two options.” As another example, if there are three or more options, the expression “at least one” as used herein means “only one option” or “any combination of two or more options.”

### (Schematic Configuration of Semiconductor Device)

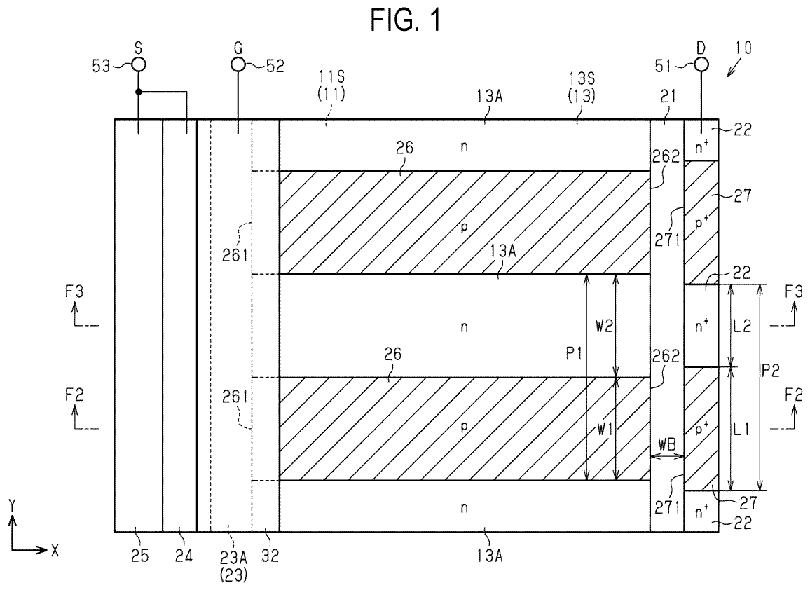

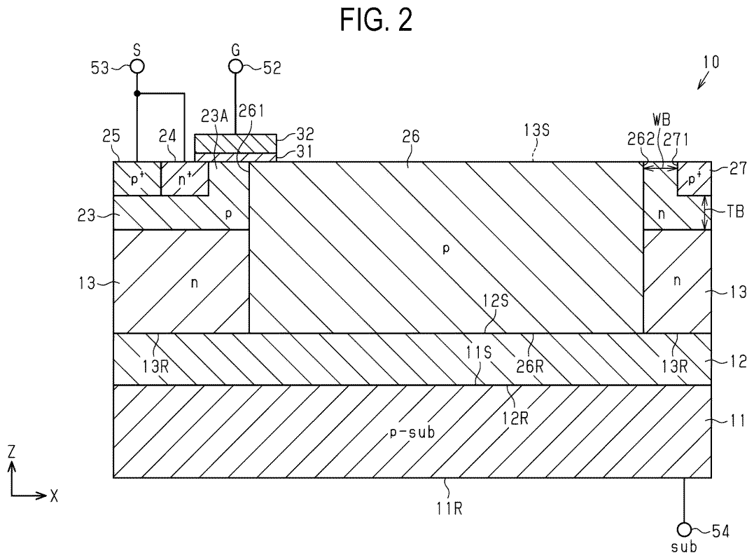

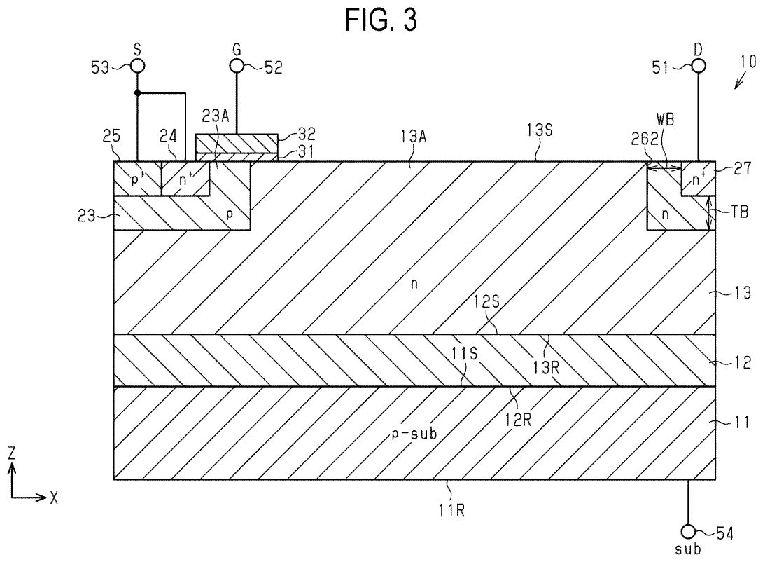

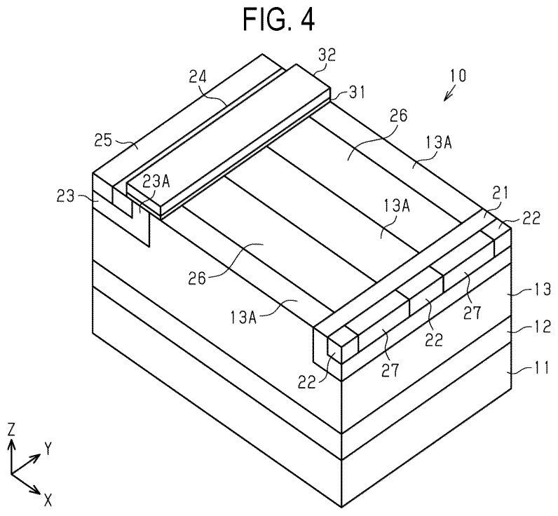

FIG. 1 is a schematic plan view of an exemplary semiconductor device according to an embodiment. FIG. 2 is a cross-sectional view of the semiconductor device, which is taken along line F2-F2 in FIG. 1. FIG. 3 is a cross-sectional view of the semiconductor device, which is taken along line F3-F3 in FIG. 1. FIG. 4 is a perspective view of the semiconductor device of FIG. 1.

As shown in FIGS. 2 to 4, the semiconductor device 10 may include a semiconductor substrate 11, an insulating layer 12, and a semiconductor layer 13. The semiconductor substrate 11 may be a silicon (Si) substrate. The semiconductor substrate 11 includes an upper surface 11S and a lower surface 11R located on the opposite side of the upper surface 11S. The semiconductor substrate 11 may be a p-substrate (referred to as “p-sub” in FIGS. 2 and 3) including p-type impurities. For example, a substrate including silicon carbide (SiC) or the like can be used as the semiconductor substrate 11.

The insulating layer 12 is provided at the upper surface 11S of the semiconductor substrate 11. The insulating layer 12 includes an upper surface 12S and a lower surface 12R located on the opposite side of the upper surface 12S. In the examples of FIGS. 2 and 3, the lower surface 12R of the insulating layer 12 is in contact with the upper surface 11S of the semiconductor substrate 11. The insulating layer 12 includes a material containing, for example, SiO₂. The insulating layer 12 may be a layer formed by oxidizing the surface of the semiconductor substrate 11. The insulating layer 12 may include, for example, a buried oxide film (BOX).

The semiconductor layer 13 is formed at the upper surface 12S of the insulating layer 12. The semiconductor layer 13 includes an upper surface 13S and a lower surface 13R located on the opposite side of the upper surface 13S. The upper surface 13S corresponds to the surface of the semiconductor layer 13. In the examples of FIGS. 2 and 3, the lower surface 13R of the semiconductor layer 13 is in contact with the upper surface 12S of the insulating layer 12. The lower surface 13R of the semiconductor layer 13 is formed to cover the entire upper surface 12S of the insulating layer 12, for example.

The semiconductor layer 13 may include, for example, an epitaxial layer. The semiconductor layer 13 includes a material containing Si. The semiconductor layer 13 contains n-type impurities. P (phosphorus), As (arsenic), Sb (antimony) or the like can be used as the n-type impurities. The semiconductor layer 13 may be, for example, a layer bonded to the semiconductor substrate 11 with the insulating layer 12 interposed therebetween. This semiconductor device 10 can be said to have an SOI structure in which the semiconductor layer 13 is formed over the semiconductor substrate 11 via the insulating layer 12.

A direction orthogonal to the upper surface 13S of the semiconductor layer 13 is a thickness direction of the semiconductor device 10. This thickness direction is referred to as a Z direction. Two directions that are orthogonal to the Z direction and are mutually orthogonal are referred to as an X direction and a Y direction, respectively. The X direction and the Y direction are directions parallel to the upper surface 13S of the semiconductor layer 13. The X direction corresponds to a “first direction.” The Y direction corresponds to a “second direction.”

### (Source Region and Drain Region)

As shown in FIGS. 1 to 3, the semiconductor device 10 may include a buffer region 21, a drain region 22, a body region 23, a source region 24, and a contact region 25. The source region 24 corresponds to a first region, and the drain region 22 corresponds to a second region.

The buffer region 21 is formed at the upper surface 13S of the semiconductor layer 13. The buffer region 21 is an n-type region which contains n-type impurities. The buffer region 21 may be a semiconductor layer formed by ion-implantation of n-type impurities into the semiconductor layer 13. As shown in FIG. 1, the body region 23 extends in the Y direction when viewed from the Z direction orthogonal to the upper surface 13S of the semiconductor layer 13.

As shown in FIGS. 2 and 3, the drain region 22 is formed at the buffer region 21. The drain region 22 contains n-type impurities. The drain region 22 has a higher impurity concentration than the body region 23. The drain region 22 is an n⁺-type region. The drain region 22 may be a semiconductor layer formed by ion-implantation of n-type impurities into the buffer region 21. As shown in FIG. 1, the drain region 22 extends in the Y direction when viewed from the Z direction.

As shown in FIGS. 2 and 3, the body region 23 is formed at the upper surface 13S of the semiconductor layer 13. The body region 23 is spaced apart from the buffer region 21 in the X direction. The body region 23 is a p-type region which contains p-type impurities. The body region 23 may be a semiconductor layer formed by ion-implantation of p-type impurities into the semiconductor layer 13. B (boron), Al (aluminum), Ga (gallium) or the like can be applied as the p-type impurities. As shown in FIG. 1, the body region 23 extends in the Y direction when viewed from the Z direction.

As shown in FIGS. 2 and 3, the source region 24 is formed at the body region 23. The source region 24 contains n-type impurities. The source region 24 may have an impurity concentration equal to the impurity concentration of the drain region 22, for example. The source region 24 is an n⁺-type region. The source region 24 may be a semiconductor layer formed by ion-implantation of n-type impurities into the body region 23. As shown in FIG. 1, the source region 24 extends in the Y direction when viewed from the Z direction.

As shown in FIGS. 2 and 3, the contact region 25 is formed at the body region 23. The contact region 25 is arranged on the opposite side of the drain region 22 with respect to the source region 24. The contact region 25 is provided so as to be in contact with the source region 24. The source region 24 contains p-type impurities. The contact region 25 has a higher impurity concentration than the body region 23, for example. The contact region 25 is a p⁺-type region. The contact region 25 may be a semiconductor layer formed by ion-implantation of p-type impurities into the body region 23. As shown in FIG. 1, the contact region 25 extends in the Y direction when viewed from the Z direction.

As shown in FIG. 3, the semiconductor layer 13 between the buffer region 21 and the body region 23 functions as a drift region 13A.

### (Column Region)

As shown in FIGS. 1 and 2, the semiconductor device 10 may include a column region 26.

The column region 26 is formed between the source region 24 and the drain region 22. The column region 26 is formed in the semiconductor layer 13. The column region 26 is a p-type region which contains p-type impurities. The column region 26 may be a semiconductor layer formed by ion-implantation of p-type impurities into the semiconductor layer 13.

As shown in FIG. 1, the column region 26 extends in the X direction when viewed from the Z direction. The column region 26 is formed in a rectangular shape and has a smaller width in the Y direction than its length in the X direction. The column region 26 is formed between the body region 23 and the buffer region 21 when viewed from the Z direction.

The column region 26 extends from the body region 23 to the buffer region 21 when viewed from the Z direction. The column region 26 includes a first end portion 261 at a side of the body region 23 and a second end portion 262 at a side of the buffer region 21. The first end portion 261 of the column region 26 is electrically coupled to the body region 23. Note that a dashed line between the body region 23 and the column region 26, which is shown in FIG. 1, is shown to conveniently distinguish between the body region 23 and the column region 26. Similarly, a solid line between the body region 23 and the column region 26, which is shown in FIG. 2, is shown to conveniently distinguish between the body region 23 and the column region 26. The second end portion 262 of the column region 26 is in contact with the buffer region 21. It can be said that the second end portion 262 of the column region 26 on the side of the buffer region 21 matches with an end portion of the buffer region 21 on the side of the source region 24.

As shown in FIG. 2, the column region 26 penetrates the semiconductor layer 13 from the upper surface 13S of the semiconductor layer 13 to the lower surface 13R of the semiconductor layer 13 in the Z direction. A lower surface 26R of the column region 26 is in contact with the upper surface 12S of the insulating layer 12.

The semiconductor device 10 of this embodiment includes a plurality of column regions 26. As shown in FIG. 1, the plurality of column regions 26 are arranged in the Y direction. It can be said that the plurality of column regions 26 are arranged in the Y direction orthogonal to the X direction in which each of the column region 26 extends. Therefore, in the semiconductor device 10, it can be said that a plurality of column regions 26 and a plurality of drift regions 13A are arranged alternately in the Y direction, which is orthogonal to the X direction in which the plurality of column regions 26 extend.

As shown in FIG. 1, a width of the column region 26 in the Y direction is referred to as W1. A width of the drift region 13A in the Y direction is referred to as W2. In this embodiment, the width W1 of the column region 26 is equal to the width W2 of the drift region 13A. Accordingly, if a difference between the width W1 of the column region 26 and the width W2 of the drift region 13A is within, for example, 10% of the width W1 of the column region 26, then it can be said that the width W1 of the column region 26 and the width W2 of the drift region 13A are equivalent to each other.

### (Collector Region)

As shown in FIGS. 1 and 2, the semiconductor device 10 may include a collector region 27.

As shown in FIG. 1, the collector region 27 is provided at the drain region 22. The collector region 27 is a p-type region which contains p-type impurities. The collector region 27 may be a semiconductor layer formed by ion-implantation of p-type impurities into the drain region 22.

The collector region 27 is selectively provided at the drain region 22. In the semiconductor device 10 in this embodiment, a plurality of collector regions 27 are arranged along the Y direction in which the drain region 22 extends. The collector region 27 is formed to divide the drain region 22 extending in the Y direction. It can be said that the drain region 22 is formed so as to arrange the plurality of collector regions 27 in the Y direction. Specifically, as shown in FIG. 1, an end portion 271 of each collector region 27 on a side of the source region 24 is in contact with the buffer region 21 in the X direction. Further, as shown in FIG. 2, an end portion 271 of each collector region 27 on a side of the semiconductor substrate 11 is in contact with the buffer region 21 in the Z direction.

As shown in FIG. 1, each collector region 27 is arranged so as to overlap the column region 26 when viewed from the X direction. In one example, each collector region 27 is arranged such that the center position of the collector region 27 in the Y direction matches the center position of the column region 26 in the Y direction. In one example, a length L2 of the drain region 22 in the Y direction is smaller than a length L1 of the collector region 27. In one example, the length L1 of the collector region 27 in the Y direction is larger than the width W1 of the column region 26 in the Y direction. Further, a length L2 of the drain region 22 in the Y direction is smaller than the width W2 of the drift region 13A in the Y direction.

Each of the plurality of column regions 26 is formed with the same width W1. Each of the plurality of drift regions 13A is formed with the width W2. The column regions 26 and the drift regions 13A are arranged alternately in the Y direction. Therefore, the sum of the width W1 of the column region 26 and the width W2 of the drift region 13A is the arrangement interval P1 at which the column region 26 and the drift region 13A are repeatedly formed. Each of the plurality of collector regions 27 is formed with the same length L1. Each of the plurality of drain regions 22 is formed with the same length L2. The collector regions 27 and the drain regions 22 are alternately arranged in the Y direction. Therefore, the sum of the length L1 of the collector region 27 and the length L2 of the drain region 22 is the arrangement interval P2 at which the collector region 27 and the drain region 22 are repeatedly formed. In this embodiment, the arrangement interval P1 at which the column region 26 and the drift region 13A are formed is equivalent to the arrangement interval P2 at which the collector region 27 and the drain region 22 are formed. Here, if a difference between the arrangement interval P1 and the arrangement interval P2 is within, for example, 10% of the arrangement interval P1, it can be said that the arrangement interval P1 and the arrangement interval P2 are equivalent to each other.

In the Y direction, the ratio of a range in which the column region 26 is formed to a range in which the column region 26 and the drift region 13A are arranged is referred to as an occupancy rate of the collector region 27. The occupancy rate of the collector region 27 is determined as a ratio of the total length of the plurality of collector regions 27 in the Y direction to a length in the Y direction of the range in which the column region 26 and the drift region 13A are arranged. The occupancy rate of the collector region 27 is greater than or equal to 20% and smaller than or equal to 90%. The occupancy rate of the collector region 27 is preferably greater than or equal to 50% and smaller than or equal to 80%.

As shown in FIG. 1, in a plan view, the buffer region 21 is arranged between the column region 26 or the drift region 13A, and both the drain region 22 and the collector region 27. Therefore, the width WB of the buffer region 21 in the X direction can be said to be a distance between both the column region 26 and the drift region 13A, and both the collector region 27 and the drain region 22. In one example, the width WB of the buffer region 21 in the X direction is longer than or equal to 5 μm and shorter than or equal to 30 μm.

As shown in FIG. 2, the buffer region 21 is arranged to be interposed between the semiconductor layer 13 and the collector region 27 in the Z direction. Therefore, a thickness TB of the buffer region 21 in the Z direction can be said to be a distance between the semiconductor layer 13 and the collector region 27. As shown in FIG. 2, the buffer region 21 is arranged between the semiconductor layer 13 and the drain region 22 in the Z direction. Therefore, the thickness TB of the buffer region 21 in the Z direction can be said to be a distance between the semiconductor layer 13 and the drain region 22. In one example, the width WB of the buffer region 21 in the X direction is equivalent to the thickness TB of the buffer region 21 in the Z direction. Here, if a difference between the width WB and the thickness TB is within, for example, 10% of the width WB, it can be said that the width WB and the thickness TB are equivalent to each other.

### (Gate Insulating Film and Gate Electrode)

As shown in FIGS. 2 and 3, a gate electrode 32 is arranged over the upper surface 13S of the semiconductor layer 13 via a gate insulating film 31. As shown in FIG. 1, the gate electrode 32 extends in the Y direction. As shown in FIGS. 2 and 3, the gate insulating film 31 and the gate electrode 32 are formed to cover the body region 23 between the source region 24 and the semiconductor layer 13 in the X direction. Further, the gate insulating film 31 and the gate electrode 32 are formed to cover a portion of the source region 24 adjacent to the body region 23. Further, the gate insulating film 31 and the gate electrode 32 are formed to cover a portion of the semiconductor layer 13 adjacent to the body region 23. The gate insulating film 31 is made of, for example, an insulating material such as silicon oxide (SiO₂), silicon nitride (SiN), or the like. The gate electrode 32 is made of, for example, a material containing conductive polysilicon or the like.

As shown in FIGS. 2 and 3, a portion of the body region 23 that faces the gate electrode 32 with the gate insulating film 31 interposed therebetween functions as a channel region 23A in which an inversion layer (channel) is formed.

### (Terminals)

As shown in FIGS. 1 to 3, the semiconductor device 10 includes terminals 51 to 54. The drain region 22 is coupled to the terminal (D) 51. The gate electrode 32 is coupled to the terminal (G) 52. The source region 24 is coupled to the terminal (S) 53. The source region 24 is coupled to the contact region 25. The terminals 51 to 53 may be, for example, pads (electrodes) configured to couple wires or the like to the semiconductor device 10. The semiconductor substrate 11 is coupled to the terminal (sub) 54. The terminal 54 may be, for example, a pad (electrode) configured to couple the semiconductor device 10 to a die pad or the like.

### (Operation)

Next, the operation of the semiconductor device 10 of this embodiment will be explained. The semiconductor device 10 includes the semiconductor layer 13 having the upper surface 13S, and the source region 24 and the drain region 22 which are spaced apart from each other in the X direction (the first direction) at the upper surface 13S when viewed from the Z direction (the thickness direction) orthogonal to the upper surface 13S. The semiconductor device 10 includes the body region 23 formed between the source region 24 and the drain region 22 at the upper surface 13S and adjacent to the source region 24, and the gate electrode 32 arranged over the body region 23. Further, the semiconductor device 10 includes the drift regions 13A and the column regions 26 which are arranged between the source region 24 and the drain region 22 and arranged alternately in the Y direction (the second direction), and the collector region 27 which is provided in the drain region 22.

A portion of the body region 23 adjacent to the source region 24 functions as the channel region 23A. The gate electrode 32 is arranged over the channel region 23A with the gate insulating film 31 interposed therebetween. The column region 26 is electrically coupled to the body region 23 and extends toward the drain region 22. Therefore, the semiconductor device 10 includes a MOSFET having a super junction structure. Due to this super junction structure, a depletion layer expands in the X direction in which the column region 26 extends. As a result, on-resistance may be reduced in the semiconductor device 10.

In the semiconductor device 10, holes are injected into the semiconductor layer 13 (the drift region 13A) from the p-type collector region 27 formed in the drain region 22, so that conductivity modulation may occur in the semiconductor layer 13. As a result, on-resistance in a large current region may be reduced in the semiconductor device 10.

The buffer region 21 is a semiconductor layer that is formed in the semiconductor layer 13 and contains n-type impurities. In one example, the buffer region 21 is formed by ion-implantation of n-type impurities into the semiconductor layer 13. The collector region 27 is a semiconductor layer that is formed in the buffer region 21 and contains p-type impurities. In one example, the collector region 27 is formed by ion-implantation of p-type impurities into the buffer region 21. The column region 26 is a semiconductor layer that is formed in the semiconductor layer 13 and contains p-type impurities. In one example, the column region 26 is formed by ion-implantation of p-type impurities into the semiconductor layer 13.

In other words, each region such as the buffer region 21 of the semiconductor device 10 of a horizontal from is formed by forming a mask such as a photoresist film on the semiconductor layer 13 and implanting ions into the semiconductor layer 13 using the mask. Therefore, a distance between the column region 26 and the collector region 27, that is, the width WB of the buffer region 21, is determined by the mask formed at the semiconductor layer 13, which is the layout design of the semiconductor device 10. Therefore, the distance between the column region 26 and the collector region 27, which is the width WB of the buffer region 21, may be formed as designed. In other words, the width WB of the buffer region 21, which is the distance between the column region 26 and the collector region 27, may be easily changed according to the design. Therefore, the degree of freedom in device design for the semiconductor device 10 can be improved. Further, the width WB of the buffer region 21, which is the distance between the column region 26 and the collector region 27, may be easily adjusted. By adjusting the width WB of the buffer region 21, which is the distance between the column region 26 and the collector region 27, it is possible to improve the electrical characteristics of the semiconductor device 10.

### (Effects)

As described above, according to this embodiment, the following effects are achieved.

(1) The semiconductor device 10 includes the semiconductor layer 13 having the upper surface 13S, and the source region 24 and the drain region 22 that are spaced apart from each other in the X direction (the first direction) at the upper surface 13S when viewed from the Z direction (the thickness direction) orthogonal to the upper surface 13S. The semiconductor device 10 includes the body region 23 formed between the source region 24 and the drain region 22 on the upper surface 13S and adjacent to the source region 24, and the gate electrode 32 arranged on the body region 23. Further, the semiconductor device 10 includes the drift regions 13A and the column regions 26 which are arranged between the source region 24 and the drain region 22 and arranged alternately in the Y direction (the second direction), and the collector region 27 which is provided in the drain region 22.

The collector region 27 is a semiconductor layer that is formed in the buffer region 21 and contains p-type impurities. The column region 26 is a semiconductor layer that is formed in the semiconductor layer 13 and contains p-type impurities. Therefore, the distance between the column region 26 and the collector region 27, that is, the width WB of the buffer region 21, may be formed as designed. In other words, the width WB of the buffer region 21, which is the distance between the column region 26 and the collector region 27, may be easily changed according to the design. Therefore, the degree of freedom in device design for the semiconductor device 10 may be improved.

(2) The width WB of the buffer region 21, which is the distance between the column region 26 and the collector region 27, may be easily changed according to the design. Therefore, by adjusting the width WB of the buffer region 21, which is the distance between the column region 26 and the collector region 27, it is possible to improve the electrical characteristics of the semiconductor device 10.

(3) A portion of the body region 23 adjacent to the source region 24 functions as the channel region 23A. The gate electrode 32 is arranged over the channel region 23A with the gate insulating film 31 interposed therebetween. The column region 26 is electrically coupled to the body region 23 and extends toward the drain region 22. Therefore, the semiconductor device 10 includes a MOSFET having a super junction structure. Due to this super junction structure, a depletion layer expands in the X direction in which the column region 26 extends. As a result, on-resistance may be reduced in the semiconductor device 10.

(4) In the semiconductor device 10, holes are injected into the semiconductor layer 13 (the drift region 13A) from the p-type collector region 27 formed in the drain region 22, so that conductivity modulation occurs in the semiconductor layer 13. As a result, on-resistance in a large current region may be reduced in the semiconductor device 10.

### [Modifications]

The aforementioned embodiment can be modified as follows, for example. The aforementioned embodiment and the following modifications can be implemented in combination unless technically contradictory. In addition, in the following modifications, the same parts as those in the aforementioned embodiment are denoted by the same reference numerals as in the aforementioned embodiment, and the explanation thereof will be omitted.
The arrangement position, shape, size, etc. of the collector region 27 may be modified as appropriate.

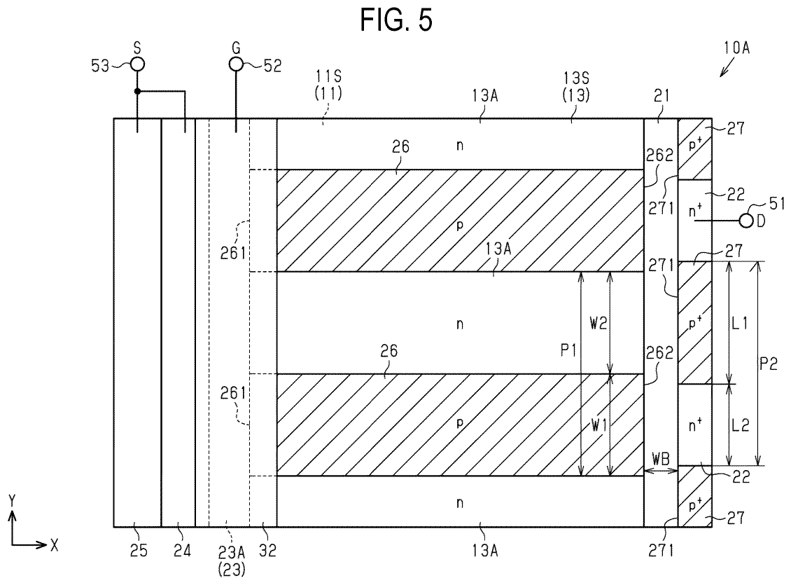

The collector region 27 of a semiconductor device 10A shown in FIG. 5 is arranged so as to overlap the entire drift region 13A when viewed from the X direction. When viewed from the X direction, the collector region 27 is arranged such that both ends of the collector region 27 in the Y direction overlap two column regions 26 adjacent to the drift region 13A that overlaps the collector region 27 in the X direction. The drain region 22 is arranged so as to overlap the column region 26 when viewed from the X direction. In this semiconductor device 10A, the occupancy rate of the collector region 27 can be set to greater than or equal to 20% and smaller than or equal to 90%, preferably greater than 50% and smaller than or equal to 80%, similarly to the aforementioned embodiment. Even in the semiconductor device 10A in which the collector region 27 and the drain region 22 are arranged in this manner, the equivalent effects as in the aforementioned embodiment may be obtained.

Further, the collector region 27 may be arranged so as to overlap one of the two column regions 26 adjacent to the drift region 13A that overlaps the collector region 27 in the X direction. Further, the drain region 22 may be arranged so as to overlap both the column region 26 and the drift region 13A when viewed from the X direction.

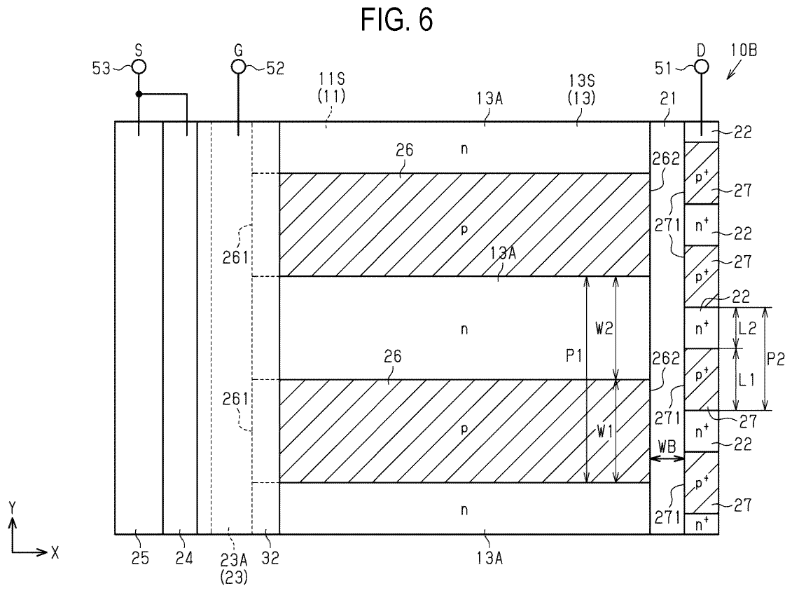

In a semiconductor device 10B shown in FIG. 6, the arrangement interval P2 between the drain region 22 and the collector region 27 is different from the arrangement interval P1 between the drift region 13A and the column region 26. In this semiconductor device 10B, the arrangement interval P2 is smaller than the arrangement interval P1. The arrangement interval P2 may be made larger than the arrangement interval P1. In this semiconductor device 10B, the occupancy rate of the collector region 27 can be set to greater than or equal to 20% and smaller than or equal to 90%, preferably greater than or equal to 50% and smaller than or equal to 80%, similarly to the aforementioned embodiment. Even in the semiconductor device 10B in which the collector region 27 and the drain region 22 are arranged in this manner, the same effects as in the aforementioned embodiment can be obtained.
The shape of the column region 26 can be modified as appropriate.

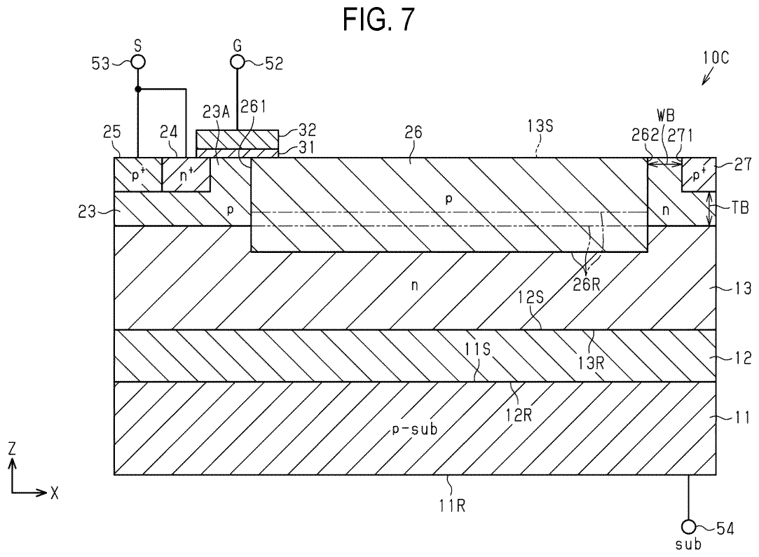

The column region 26 of a semiconductor device 10C shown in FIG. 7 is spaced apart from the insulating layer 12 in the Z direction. In this semiconductor device 10C, the lower surface 26R of the column region 26 is located between the body region 23 and the insulating layer 12.

Further, the column region 26 may be formed to have a same depth from the upper surface 13S of the semiconductor layer 13 as a depth of the body region 23, in the Z direction. Further, the column region 26 may be formed to have a same depth from the upper surface 13S of the semiconductor layer 13 as a depth of the buffer region 21, in the Z direction. Further, the column region 26 may be formed to have a shallower depth from the upper surface 13S of the semiconductor layer 13 than a depth of the body region 23, in the Z direction.

Further, each column region 26 may be formed to extend between the insulating layer 12 and the body region 23 in FIG. 2. A plurality of column regions 26 arranged in the Y direction may be electrically coupled by a portion between the insulating layer 12 and the body region 23.
Although the semiconductor device 10 of the aforementioned embodiment has an SOI structure, it may be a semiconductor device that does not have an SOI structure.

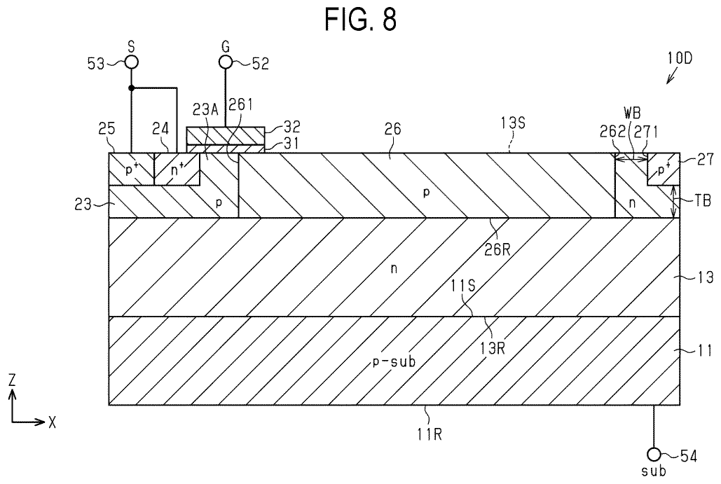

In a semiconductor device 10D shown in FIG. 8, the semiconductor layer 13 is formed on the semiconductor substrate 11. The lower surface 13R of the semiconductor layer 13 is in contact with the upper surface 11S of the semiconductor substrate 11. In this semiconductor device 10D, in one example, the same voltage as the voltage applied to the drain region 22 may be applied to the semiconductor substrate 11.
The depth of the body region 23 and the depth of the buffer region 21 in the Z direction may be made different.
It may be configured as a semiconductor device including an IGBT (Insulated Gate Bipolar Transistor). In this case, the source region 24 functions as an emitter region, the drain region 22 functions as a collector region, and the drift region 13A functions as a base region.

The term “on” as used in the present disclosure includes the meanings of “on” and “above” unless clearly stated otherwise in the context. Therefore, the expression “a first layer is formed on a second layer” is intended that in some embodiments, the first layer can be directly arranged on the second layer in contact with the second layer, while in other embodiments, the first layer can be arranged above the second layer without contacting the second layer. That is, the term “on” does not exclude a structure in which other layers are formed between the first and second layers.

The Z direction used in the present disclosure does not necessarily have to be the vertical direction, and it does not have to be exactly the same as the vertical direction. Therefore, various structures (for example, the structure shown in FIG. 1) according to the present disclosure are not limited to the Z-axis direction “upper” and “lower” described herein being the vertical direction “upper” and “lower.” For example, the X-axis direction may be the vertical direction, or the Y-axis direction may be the vertical direction.

### Supplementary Notes

The technical ideas that can be understood from the above-described embodiments are described below. In addition, for the purpose of aiding understanding and not for the purpose of limitation, components described in supplementary notes are labeled with the reference numerals of the corresponding components in the embodiments. The reference numerals are provided as examples to aid understanding, and the components described in supplementary notes should not be limited to the components indicated by the reference numerals.

### (Supplementary Note 1)

A semiconductor device including:
a semiconductor layer (13) having a surface (13S);
a first region (24) and a second region (22) of a first conductivity type (n), which are spaced apart from each other in a first direction (X) at the surface (13S) and extend in a second direction (Y) orthogonal to the first direction (X), when viewed from a thickness direction (Z) orthogonal to the surface (13S);
a channel region (23A) of a second conductivity type (p), which is formed between the first region (24) and the second region (22) at the surface (13S) and is adjacent to the first region (24);
a gate electrode (32) arranged over the channel region (23A) via a gate insulating film (31);
a plurality of drift regions (13A) of the first conductivity type (n) and a plurality of column regions (26) of the second conductivity type (p), which are arranged between the channel region (23A) and the second region (22) and are alternately arranged in the second direction (Y);
a buffer region (21) of the first conductivity type (n), which is provided between the second region (22) and both the drift region (13A) and the column region (26) and; and
at least one collector region (27) of the second conductivity type (p), which is provided in the second region (22).

### (Supplementary Note 2)

The semiconductor device of Supplementary Note 1, wherein the at least one collector region includes a plurality of collector regions (27), and the plurality of collector regions (27) are spaced apart from each other in the second direction (Y).

### (Supplementary Note 3)

The semiconductor device of Supplementary Note 1 or 2, wherein in the second region (22), an occupancy rate of the collector region (27), which is a ratio of a total length of at least one collector region (27) in the second direction (Y) to a range in which the drift regions (13A) and the column regions (26) are arranged in the first direction (X), is greater than or equal to 20% and smaller than or equal to 90%.

### (Supplementary Note 4)

The semiconductor device of Supplementary Note 3, wherein the occupancy rate is greater than or equal to 50% and smaller than or equal to 80% or less.

### (Supplementary Note 5)

The semiconductor device of any one of Supplementary Notes 1 to 4, wherein the arrangement interval (P2) of the plurality of collector regions (27) in the second direction (Y) is smaller than the arrangement interval (P1) of the plurality of column regions (26) in the second direction (Y).

### (Supplementary Note 6)

The semiconductor device of any one of Supplementary Notes 1 to 5, wherein the collector region (27) and the second region (22) are arranged such that the buffer region (21) is interposed between the semiconductor layer (13) and both the collector region (27) and the second region (22) in the thickness direction (Z), and
wherein the collector region (27) extends from the surface (13S) of the semiconductor layer (13) to the buffer region (21) in the thickness direction (Z).

### (Supplementary Note 7)

The semiconductor device of any one of Supplementary Notes 1 to 6, wherein a width (WB) of the buffer region (21) in the first direction (X) is longer than or equal to 5 μm and shorter than or equal to 30 μm.

### (Supplementary Note 8)

The semiconductor device of any one of Supplementary Notes 1 to 7, wherein the thickness (TB) of the buffer region (21) in the thickness direction (Z) is equal to the width (WB) of the buffer region (21) in the first direction (X).

### (Supplementary Note 9)

The semiconductor device of any one of Supplementary Notes 1 to 8, wherein the collector region (27) is arranged at a position overlapping with at least one of the column regions (26) when viewed from the first direction (X).

### (Supplementary Note 10)

The semiconductor device of any one of Supplementary Notes 1 to 9, wherein the collector region (27) is arranged between two adjacent column regions in the second direction (Y).

(Supplementary Note 11) The semiconductor device of any one of Supplementary Notes 1 to 10, further including:

a semiconductor substrate (11); and

an insulating layer (12) provided over the semiconductor substrate (11),
wherein the semiconductor layer (13) is provided over the insulating layer (12).
   (Supplementary Note 12) The semiconductor device of any one of Supplementary Notes 1 to 10, further including:
a semiconductor substrate (11),
wherein the semiconductor layer (13) is in contact with the upper surface (11S) of the semiconductor substrate (11).

The above description is merely an example. Those skilled in the art will appreciate that more possible combinations and substitutions are possible beyond the components and methods (manufacturing processes) listed for the purposes of illustrating the techniques of the present disclosure. The present disclosure is intended to cover all alternatives, modifications, and changes that fall within the scope of the present disclosure, including the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a semiconductor layer having a surface;
a first region and a second region of a first conductivity type, which are spaced apart from each other in a first direction at the surface and extend in a second direction orthogonal to the first direction, when viewed from a thickness direction orthogonal to the surface;
a channel region of a second conductivity type, which is formed between the first region and the second region at the surface and is adjacent to the first region;
a gate electrode arranged over the channel region via a gate insulating film;
a plurality of drift regions of the first conductivity type and a plurality of column regions of the second conductivity type, which are arranged between the channel region and the second region and are alternately arranged in the second direction;
a buffer region of the first conductivity type, which is provided between the second region and both the drift regions and the column regions; and
at least one collector region of the second conductivity type, which is provided in the second region.

2. The semiconductor device of claim 1, wherein the at least one collector region includes a plurality of collector regions, and the plurality of collector regions are spaced apart from each other in the second direction.

3. The semiconductor device of claim 1, wherein in the second region, an occupancy rate of the collector region, which is a ratio of a total length of the at least one collector region in the second direction to a range in which the drift regions and the column regions are arranged in the second direction, is greater than or equal to 20% and smaller than or equal to 90%.

4. The semiconductor device of claim 3, wherein the occupancy rate is greater than or equal to 50% and smaller than or equal to 80%.

5. The semiconductor device of claim 2, wherein an arrangement interval of the plurality of collector regions in the second direction is smaller than an arrangement interval of the plurality of column regions in the second direction.

6. The semiconductor device of claim 1, wherein the collector region and the second region are arranged such that the buffer region is interposed between the semiconductor layer and both the collector region and the second region, in the thickness direction, and
wherein the collector region extends from the surface of the semiconductor layer to the buffer region in the thickness direction.

7. The semiconductor device of claim 1, wherein a width of the buffer region in the first direction is longer than or equal to 5 μm and shorter than or equal to 30 μm.

8. The semiconductor device of claim 1, wherein a thickness of the buffer region in the thickness direction is equal to a width of the buffer region in the first direction.

9. The semiconductor device of claim 1, wherein the collector region is arranged at a position overlapping with at least one of the plurality of column regions when viewed from the first direction.

10. The semiconductor device of claim 1, wherein the collector region is arranged between two adjacent column regions in the second direction.

11. The semiconductor device of claim 1, further comprising:
a semiconductor substrate; and
an insulating layer provided over the semiconductor substrate,
wherein the semiconductor layer is provided over the insulating layer.

12. The semiconductor device of claim 1, further comprising:
a semiconductor substrate,
wherein the semiconductor layer is in contact with an upper surface of the semiconductor substrate.
